(19) United States
(12) Patent Application Publication
(10) Pub. No.: US 2025/0279337 A1
(43) Pub. Date: Sep. 4, 2025

(54) STACKED CHIP PACKAGE STRUCTURE AND METHOD FOR FORMING THE SAME

(71) Applicant: HEFEI SMAT TECHNOLOGY CO. LTD., HEFEI CITY (CN)

(72) Inventor: Xiaochun TAN, HEFEI CITY (CN)

(21) Appl. No.: 19/066,287

(22) Filed: Feb. 28, 2025

(30) Foreign Application Priority Data
Feb. 29, 2024 (CN) 202410225320.0

(51) Int. Cl. H01L 23/495; H01L 21/56; H01L 23/31; H01L 23/538; H01L 25/07

(52) U.S. Cl. CPC H01L 23/4952; H01L 21/561; H01L 23/3135; H01L 23/49548; H01L 23/49568; H01L 23/5384; H01L 25/074; H01L 2225/06506; H01L 2225/06524

(57) ABSTRACT

A stacked chip package structure and a method for forming the same are disclosed. The stacked chip package structure includes a lower encapsulant encapsulating a first chip, with a wiring layer on its upper surface and a leadframe on its lower surface, and an upper encapsulant encapsulating a second chip. The internal pads of the first and second chips are disposed opposite each other and electrically coupled via wirings. The wirings connect to the leadframe leads through conductive vias. This structure reduces PCB footprint and wiring space. The heat sink island in the leadframe efficiently transfers heat from both chips to the exterior, improving heat dissipation and device reliability. The packaging method sequentially forms the lower encapsulant, interconnect structure, and upper encapsulant.

### CROSS-REFERENCE TO PRIOR APPLICATIONS

This application claims priority to Chinese Patent Application No. 202410225320.0, filed on Feb. 29, 2024, entitled “PACKAGE STRUCTURE WITH STACKED PARALLEL CHIPS AND PACKAGING METHOD THEREOF,” the contents of which are incorporated herein by reference, including the full text of the specification, claims, drawings, and abstract.

### TECHNICAL FIELD

The present disclosure belongs to the technical field of chip packaging, in particular to a stacked chip package structure and a method for forming the same.

### BACKGROUND

With the continuous advancement of science and technology, an increasing number of electronic devices are widely used in daily life and work, bringing great convenience and becoming indispensable tools. The primary components that enable various functions in electronic devices are chips. To ensure the reliability, service life, and protection from external factors, chips require packaging.

A metal-oxide-semiconductor chip, abbreviated as MOS chip, is a key component in integrated circuits, composed of metal-oxide-semiconductor field-effect transistors (MOSFETs, referred to as MOS transistors). In electronic circuits, MOS chips are typically used in amplifier or switching circuits.

Conventional MOS chips are generally packaged individually and then surface-mounted onto designated areas of a printed circuit board (PCB). For electronic circuits composed of multiple MOS chips, each chip is installed separately, and their interconnections are established on the PCB. This structure requires a large mounting space and routing area on the PCB, leading to a relatively large overall circuit size, which fails to meet packaging requirements.

### SUMMARY

In order to solve the above problems in the prior art, the present disclosure provides a stacked chip package structure and a method for forming the same.

According to an aspect of the present disclosure, there is provided a stacked chip package structure, comprising: a lower encapsulant having a wiring layer on an upper surface of the lower encapsulant, a leadframe on a lower surface of the lower encapsulant, and a first chip encapsulated therein, the wiring layer comprising a plurality of wirings; and an upper encapsulant above the lower encapsulant and encapsulating a second chip therein, wherein a plurality of internal pads of the first chip are disposed opposite to a plurality of internal pads of the second chip and are electrically coupled with each other via the plurality of wirings, thereby electrically coupling the first chip and the second chip within the stacked chip package structure, and the plurality of wirings are coupled to a plurality of leads of the leadframe via a plurality of conductive vias within the lower encapsulant.

Optionally, the first chip and the second chip are a first MOS transistor and a second MOS transistor, respectively.

Optionally, a source, a gate, and a drain of the first MOS transistor are electrically coupled to a source, a gate, and a drain of the second MOS transistor, respectively, via the wiring layer.

Optionally, the leadframe comprises a heat sink island, a first surface of the first MOS transistor is formed with the plurality of internal pads, and a second surface of the first MOS transistor is opposite to the first surface and adhered to the heat sink island.

Optionally, the stacked chip package structure further comprises: a plurality of external pads on the lower surface of the lower encapsulant and electrically coupled to the plurality of leads, respectively.

Optionally, the plurality of internal pads of the second chip are adhered to the wiring layer using a conductive adhesive to achieve electrical connection.

Optionally, each of the plurality of wirings has a recess; and the plurality of internal pads of the second chip are positioned within the respective recesses to achieve electrical connection.

Optionally, the second chip is secured to the upper surface of the lower encapsulant using an insulating adhesive.

Optionally, the plurality of wirings are located in wiring layers of different levels, at least one internal pad of the first chip is coupled to a respective wiring via a conductive via, and at least one internal pad of the second chip is coupled to a respective wiring via a conductive via.

According to another aspect of the present disclosure, there is provided a method for forming a stacked chip package structure, comprising: mounting a first chip upwards on a heat sink island of a leadframe; forming a lower encapsulant encapsulating the first chip and the leadframe, with a plurality of internal pads of the first chip being exposed on an upper surface of the lower encapsulant, and with the heat sink island and a plurality of leads of the leadframe being exposed on a lower surface of the lower encapsulant; forming an interconnect structure comprising a plurality of wirings on the upper surface of the lower encapsulant, and a plurality of conductive vias penetrating the lower encapsulant to the plurality of leads; mounting a second chip downwards on the lower encapsulant such that a plurality of internal pads of the first chip and a plurality of internal pads of the second chip are disposed opposite to each other and are electrically coupled via the plurality of wirings; and forming an upper encapsulant above the lower encapsulant and encapsulating the second chip, wherein the wiring layer electrically couples the first chip and the second chip within the stacked chip package structure.

Optionally, the first chip and the second chip are a first MOS transistor and a second MOS transistor, respectively.

Optionally, a source, a gate, and a drain of the first MOS transistor are electrically coupled to a source, a gate, and a drain of the second MOS transistor, respectively, via the wiring layer.

Optionally, mounting the second chip downwards on the lower encapsulant comprises: adhering the plurality of internal pads of the second chip to the wiring layer using a conductive adhesive to achieve electrical connection.

Optionally, mounting the second chip downwards on the lower encapsulant comprises: forming recesses in the plurality of wirings, respectively; and positioning the plurality of internal pads of the second chip within the respective recesses to achieve electrical connection.

Optionally, mounting the second chip downwards on the lower encapsulant further comprises: securing the second chip to the upper surface of the lower encapsulant using an insulating adhesive.

Optionally, forming the interconnect structure comprises: forming the plurality of wirings in wiring layers of different levels; and at least one internal pad of the first chip is coupled to a corresponding wiring via a conductive via; and at least one internal pad of the second chip is coupled to a corresponding wiring via a conductive via.

In the stacked chip package structure of the present disclosure, two chips are stacked during the packaging process, with the internal electrical connection between the two chips realized through the wiring layer within the package structure. This eliminates the need to install the two chips on the PCB and connect them via wiring. The PCB no longer requires a large area for chip installation and wiring, significantly reducing the PCB footprint and simplifying the structure.

In a preferred embodiment, the heat sink island of the leadframe is exposed, enabling quick transfer of the working heat from the two chips to the exterior of the package for effective heat dissipation. In a further preferred embodiment, external pads located on the lower surface of the stacked chip package structure are electrically coupled to the leads of the leadframe. This arrangement creates a gap between the exposed surface of the heat sink island and the surface of the printed circuit board, allowing airflow beneath the heat sink island. This enhances the heat dissipation effect and improves the device's reliability.

In a preferred embodiment, the internal pads of the upper chip are secured to the wiring layer using a conductive adhesive to establish an electrical connection, while the upper chip is adhered and secured to the surface of the lower encapsulant using an insulating adhesive. Since the conductive adhesive and insulating adhesive are used before the molding process, the internal pads of the second chip are aligned with those of the first chip, which improves the yield of the stacked chip package structure.

In a preferred embodiment, recesses are formed in multiple wiring paths within the wiring layer of the package structure to accommodate the internal pads of the upper chip, ensuring alignment and direct electrical contact between the upper and lower chips. In a further preferred embodiment, the upper chip is adhesively secured to the surface of the lower encapsulant using an insulating adhesive. The direct electrical contact between the second chip and the wiring layer enables both internal and external electrical connections of the package structure to carry large currents, reducing the line losses of the device and increasing its rated power, as no conductive adhesive is used.

In a preferred embodiment, the multiple wirings of the wiring layer are located at different levels. The wiring layer serves as both the internal and external electrical connection path between the first and second chips, requiring only the external pads of a single chip for the two chips' external electrical connection. Additionally, for MOS chips, designing multiple wirings at different levels effectively reduces electric-field coupling between wirings and minimizes the risk of breakdown due to insufficient insulation. This significantly enhances the withstand voltage characteristics and long-term reliability of the MOS chips.

### BRIEF DESCRIPTION OF THE DRAWINGS

FIG. 1 shows an internal schematic circuit diagram of a stacked chip package structure according to the present disclosure;

FIG. 2 shows a perspective view of a stacked chip package structure according to a first embodiment of the present disclosure;

FIG. 3a and FIG. 3b respectively show a top view and a cross-sectional view of the stacked chip package structure according to a first embodiment of the present disclosure;

FIGS. 4a to FIG. 4f show cross-sectional views of different stages of a method for forming a stacked chip package structure according to a second embodiment of the present disclosure;

FIG. 5 shows a perspective view of a stacked chip package structure according to a third embodiment of the present disclosure;

FIG. 6 shows a perspective view of a stacked chip package structure according to a fourth embodiment of the present disclosure.

### DETAILED DESCRIPTION

In order to better understand the purpose, structure, and function of the present disclosure, a stacked chip package structure and a method for forming the same proposed by the present disclosure will be described in further detail below with reference to the accompanying drawings.

The chip is designed to meet the specific requirements of the product. Some chips consist of a single MOS transistor, while others integrate multiple MOS transistors. In electronic devices, a MOS chip with multiple channels can be used in power amplifier circuits, filter circuits, switching circuits, and similar applications.

Conventional MOS transistors are typically packaged separately and mounted in designated areas on a printed circuit board (PCB). For electronic circuits requiring multiple MOS chips, each chip is first installed individually, and then series or parallel connections are made between the chips on the PCB. This approach requires reserving more space for device mounting and circuit routing on the PCB, resulting in a larger overall circuit size, which does not meet packaging constraints.

In contrast, the stacked chip package structure described in the present disclosure addresses these challenges by vertically stacking two chips and using the wiring layer inside the package to establish the electrical connection between them. This design not only significantly reduces the footprint of the chips on the PCB but also simplifies the circuit wiring layout, enhancing packaging efficiency and reliability. The stacked chip package structure can be applied regardless of the type or number of MOS transistors integrated on the chip. The following example depicts the stacked package structure with two N-channel enhancement-type MOS transistors.

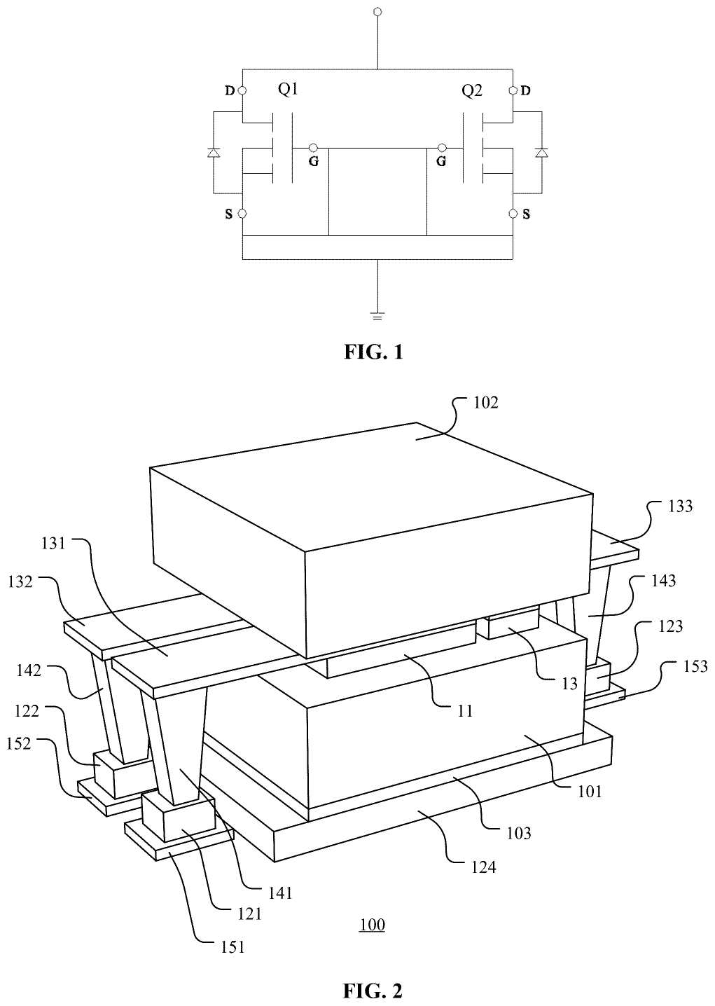

FIG. 1 shows an internal schematic circuit diagram of a stacked chip package structure according to the present disclosure.

The stacked chip package structure comprises a first chip and a second chip. The first chip comprises a MOS transistor Q1, and the second chip comprises a MOS transistor Q2. A MOS transistor may be of the type of field-effect transistor (FET) (the other type is a junction field-effect transistor, or JFET). It mainly has two structural forms: N-channel type and P-channel type. Based on different field-effect principles, MOS transistors are classified into depletion mode (where a large drain current exists when the gate voltage is zero) and enhancement mode (where the drain current is zero when the gate voltage is zero, and a certain gate voltage must be applied to allow the drain current to flow). Consequently, MOS transistors can be produced in four varieties: P-channel enhancement, P-channel depletion, N-channel enhancement, and N-channel depletion. Each MOS transistor has three terminals: a Gate (denoted as “G”), a Source (denoted as “S”), and a Drain (denoted as “D”). For connections, in an N-channel transistor, power is input to the Drain (D), and output is at the Source (S); for a P-channel transistor, power is input at the Source (S), and output is at the Drain (D). The connections for enhancement and depletion types are essentially the same.

The MOS transistors Q1 and Q2 are, for example, N-channel enhancement-type single MOS transistors. However, the present disclosure is not limited thereto, and as described above, the MOS transistors Q1 and Q2 may be any type of MOS transistor. Inside the stacked chip package structure, the source S, the drain D, and the gate G of the MOS transistor Q1 are electrically coupled to the source S, the drain D, and the gate G of the MOS transistor Q2, respectively, thereby realizing the parallel connection of the MOS transistors Q1 and Q2. The stacked chip package structure comprises external pads, including a source pad, a drain pad, and a gate pad, shared by MOS transistors Q1 and Q2. The number of external pads is equal to that of a single MOS transistor, reducing the mounting and wiring space compared with multiple MOS transistors.

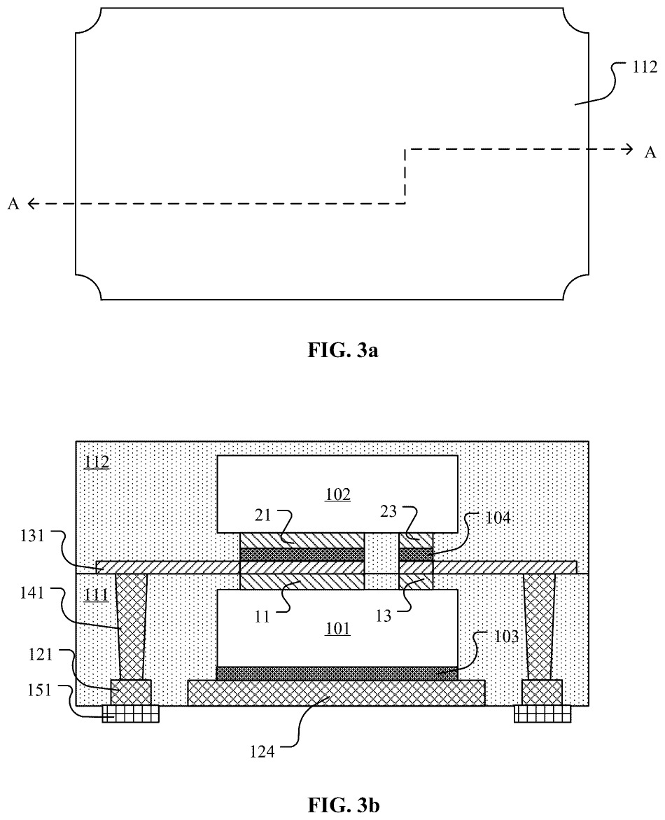

Referring to FIGS. 2, 3a, and 3b, there are shown a perspective view, a top view, and a cross-sectional view, respectively, of a stacked chip package structure according to a first embodiment of the present disclosure. For the sake of clarity, a lower encapsulant 111 for encapsulating the first chip 101 and an upper encapsulant 112 for encapsulating the second chip 102 are not shown in FIG. 2. Further, in the top view of FIG. 3a, the cross-sectional position of the cross-sectional view shown in FIG. 3b is indicated by line AA.

The stacked chip package structure 100 includes a lower encapsulant 111 and an upper encapsulant 112. The first chip 101 and the second chip 102 are encapsulated within the lower encapsulant 111 and the upper encapsulant 112, respectively. Both the first chip 101 and the second chip 102 are MOS chips, which may contain a single MOS transistor or integrate multiple MOS transistors. For the purposes of this disclosure, a single MOS transistor is used as an example. The first surface of the first chip 101 faces, or is opposite to, the first surface of the second chip 102.

A wiring layer with a plurality of wirings 131-133 is formed on the upper surface of the lower encapsulant 111. On the first surface of the first chip 101, internal pads 11-13 of the source, the gate, and the drain are formed, respectively, exposed to the upper surface of the lower encapsulant 111 and in contact with the plurality of wirings 131-133. The first surface of the second chip 102 is formed with internal pads 21-23 of the source, gate, and drain, which are electrically coupled to the plurality of wirings 131-133 of the wiring layer via conductive adhesive 104. Inside the stacked chip package structure 100, the source, the gate, and the drain of the first chip 101 and the source, the gate, and the drain of the second chip 102 are internally electrically coupled to each other via the wiring layer. Preferably, the first surface of the second chip 102 may be further coated with an insulating adhesive to adhere and secure it to the upper surface of the lower encapsulant 111.

Further, the plurality of wirings 131-133 of the wiring layer are electrically coupled to the plurality of leads 121-123 of the leadframe, respectively, via the plurality of conductive vias 141-143. The first chip 101 and the second chip 102 are stacked and electrically coupled to each other inside the package structure. Each of the MOS transistors inside the first chip 101 and the second chip 102 has a source, a gate, and a drain. The source, gate, and drain of the first chip 101 and the second chip 102 are respectively coupled to each other via corresponding wirings, thereby realizing the electrical parallel connection of the chip pads inside the package structure.

Further, the second surface of the first chip 101 is secured to the heat sink island 124 of the leadframe using adhesive 103. The plurality of leads 121-123 of the leadframe are exposed on the lower surface of the lower encapsulant 111 along with the thermally conductive island 124. Further, external pads 151-153 are formed on the exposed surfaces of the plurality of leads 121-123 of the leadframe.

According to the stacked chip package structure of this embodiment, two chips are stacked in the packaging process, and the internal electrical connection of the two chips is realized using the wiring layer inside the package structure. It is not necessary to mount the two chips on the PCB and then perform the wiring electrical connection between the two chips. The PCB does not need to reserve the mounting and wiring space for the two chips, significantly reducing the packaging size and simplifying the structure.

According to the stacked chip package structure of this embodiment, the heat sink island exposed in the leadframe is used to quickly transfer the working heat of the two chips to the outside of the package, thereby achieving heat dissipation. In a further preferred embodiment, the external pads located on the lower surface of the stacked chip package structure are electrically coupled to the leads of the leadframe, creating a gap between the exposed surface of the heat sink island and the surface of the printed circuit board. This gap allows for airflow, thereby further improving the heat dissipation effect and enhancing device reliability.

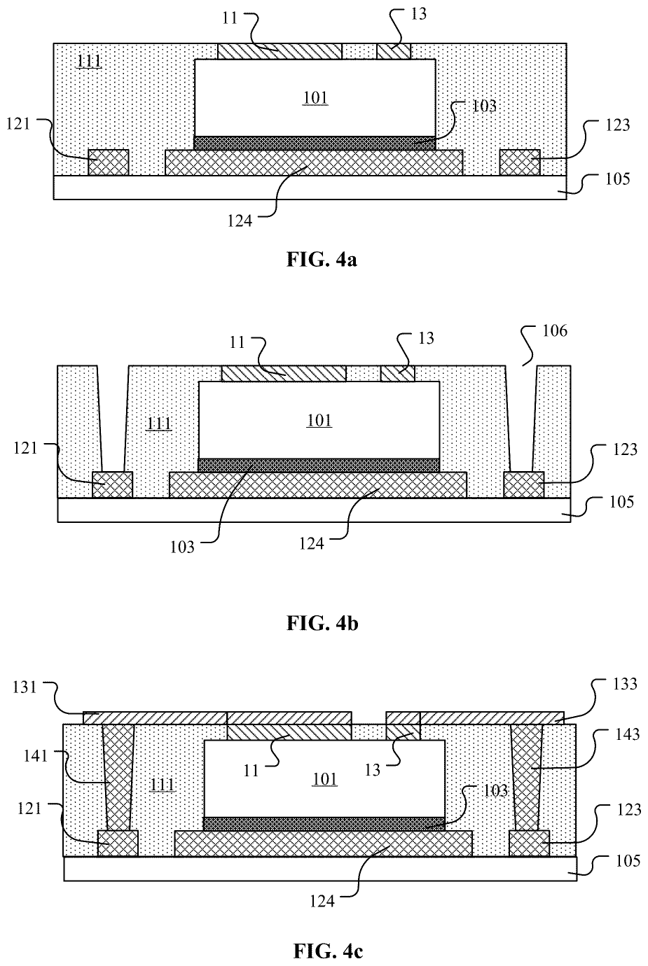

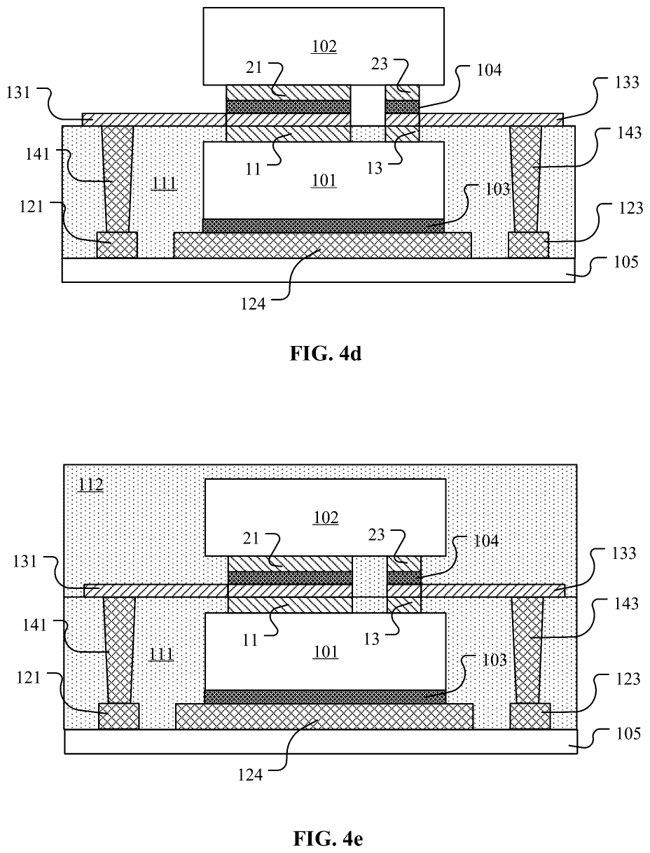

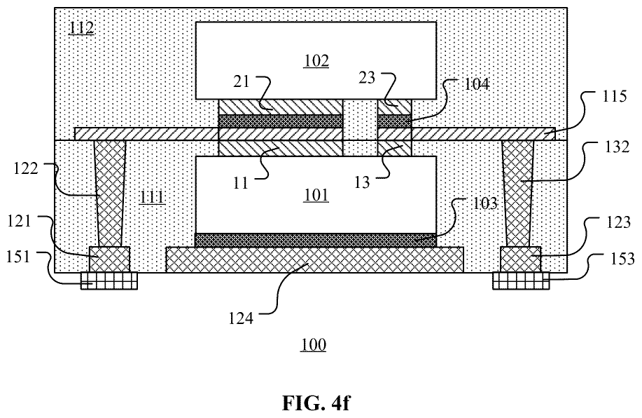

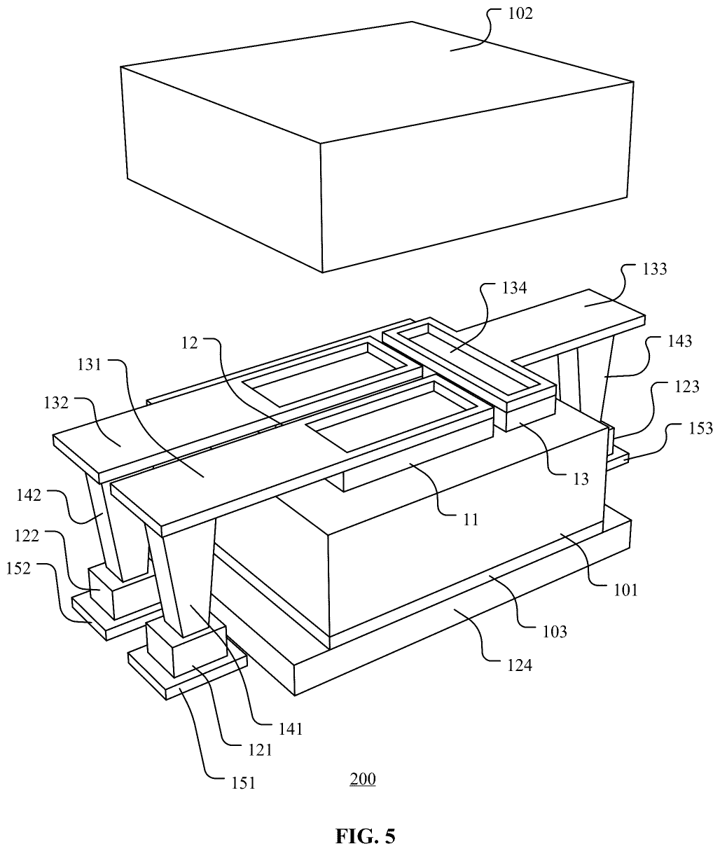

Please refer to FIGS. 4a to 4f, which are cross-sectional views of various steps of a method for forming a stacked chip package structure according to an embodiment of the present disclosure. FIGS. 4a to 4f are taken at the same position as FIG. 3b, i.e., along the line AA shown in FIG. 3a.

The encapsulation method comprises the following main steps:

S1: The first chip 101 is mounted on the heat sink island 124 of the leadframe (the plurality of leads 121-123 of the leadframe and the heat sink island 124 are shown in the drawing).

S2: Form a lower encapsulant 111 encapsulating the first chip 101 and the leadframe, exposing a plurality of internal pads 11-13 of the first chip 101 on the upper surface of the lower encapsulant 111, and exposing the heat sink island 124 and a plurality of leads 121-123 of the leadframe on the lower surface of the lower encapsulant 111.

S3: Form an interconnect structure including a plurality of wirings 131-133 located on the upper surface of the lower encapsulant 111 and a plurality of conductive vias 141-143 penetrating the lower encapsulant 111 to the plurality of leads 121-123.

S4: Mount the second chip 102 on the lower encapsulant 111 such that the plurality of internal pads 11-13 of the first chip 101 and the plurality of internal pads 21-23 of the second chip 102 are disposed opposite each other and are electrically coupled via the plurality of wirings 131-133 of the wiring layer.

S5: Form an upper encapsulant 112 above the lower encapsulant 111 to encapsulate the second chip 102.

Detailed steps of the method for forming the stacked chip package structure according to the present disclosure are further described below with reference to FIGS. 4a to 4f.

Referring to FIG. 4a, the first chip 101 is mounted on the heat sink island 124 of the leadframe, and the lower encapsulant 111 is formed.

In this step, a substrate 105 is provided on which a leadframe including a heat sink island 124 and leads 121-123 is placed. The substrate 105 is a commonly used substrate in the art, such as a copper-clad laminate. The leadframe is a carrier commonly used in the art, specifically composed of a heat sink island 124 and leads 121-123 arranged around the heat sink island 124. Multiple leadframes can be placed on the substrate 105 according to the size to realize batch manufacturing of multiple stacked chip package structures. The present disclosure takes placing a leadframe to fabricate a single chip stack package as an example.

Inner pads 11-13 of the source, gate, and drain are formed on the first surface of the first chip 101, with the second surface being opposite to the first surface. The second surface of the first chip 101 is secured to the heat sink island 124 of the leadframe using adhesive 103. Then, a lower encapsulant 111 is formed to encapsulate the first chip 101 and the leadframe. For example, the lower encapsulant 111 is formed by injection molding of a plastic encapsulant, and the plastic encapsulant used in the present disclosure is an epoxy resin plastic encapsulant, which has low cost and good curing performance.

Then, the upper surface of the lower encapsulant 111 is polished flat, and the internal pads 11-13 on the first surface of the first chip 101 are re-exposed. Since the leadframe is placed on the substrate 105, the plurality of leads 121-123 and the heat sink island 124 of the leadframe are in contact with the surface of the substrate 105 and are exposed on the lower surface of the lower encapsulant 111.

Referring to FIG. 4b, holes are drilled in the lower encapsulant 111 to form a plurality of through-holes 106 that reach the plurality of leads 121-123 of the leadframe.

In this step, laser drilling or plasma etching is used to remove the resin material in selected regions of the lower encapsulant 111, thereby forming a plurality of through-holes 106 penetrating the lower encapsulant 111. Compared with plasma etching, laser drilling can achieve faster processing speed and micron-sized hole diameters, which helps to improve the production efficiency and yield of the package structure.

Referring to FIG. 4c, a wiring layer including a plurality of wirings 131-133 is formed on the upper surface of the lower encapsulant 111.

In this step, a seed layer is formed on the upper surface of the lower encapsulant 111 by electroless plating, and a conductive layer is formed on the seed layer by plating. The conductive layer not only covers the upper surface of the lower encapsulant 111 but also fills the plurality of through-holes 106 penetrating the lower encapsulant 111, thereby forming the plurality of conductive vias 141-143. Then, the conductive layer and the seed layer are etched to form a pattern of the plurality of wirings 131-133. Alternatively, after the seed layer is formed, the seed layer is etched to form a pattern of the plurality of wirings 131-133, and then a conductive layer is formed on the seed layer by plating. Since plating can only generate a conductive layer on the surface of the seed layer, the conductive layer obtained after plating also has a pattern of a plurality of wirings 131-133.

In the above-described step, the plurality of wirings 131-133 of the wiring layer are located at the same level and have substantially the same thickness, allowing the plurality of wirings 131-133 for the source, the drain, and the gate of the first chip 101 to be formed in the same step. In an alternative step, the thickness of the wirings 131 and 132 required for the source and drain of the first chip 101 is greater than the thickness of the wiring 133 required for the gate of the first chip 101, and the plurality of wirings 131-133 for the source, drain, and gate of the first chip 101 are formed respectively using different steps.

Referring to FIG. 4d, the second chip 102 is mounted on the upper surface of the lower encapsulant 111.

In this step, the first surface of the second chip 102 and the first surface of the first chip 101 are placed opposite each other. Internal pads 21-23 of the source, gate, and drain are formed on the first surface of the second chip 102, with the second surface being opposite to the first surface. The internal pads 21-23 of the second chip 102 are respectively secured to the wirings 131-133 of the wiring layer using conductive adhesive 104, thereby realizing the internal electrical connection between the second chip 102 and the first chip 101. In a preferred embodiment, an insulating adhesive may also be used to secure the entire first surface of the second chip 102 on the upper surface of the lower encapsulant 111, so that the internal pads 21-23 of the second chip 102 and the internal pads 11-13 of the first chip 101 are maintained in position alignment during the injection molding of the plastic package, thereby improving the yield of the stacked chip package structure.

In the present embodiment, the source, drain, and gate of the MOS transistor in the second chip 102 are electrically coupled to the source, drain, and gate of the MOS transistor in the first chip 101, respectively, thereby coupling the MOS transistor in the second chip 102 in parallel with the MOS transistor in the first chip 101.

Further, the wirings 131-133 of the wiring layer are electrically coupled to the plurality of leads 121-123 of the leadframe via the plurality of conductive vias 141-143, thereby realizing external electrical connections between the second chip 102 and the first chip 101. The wiring layer serves as both an internal electrical connection and an external electrical connection path between the second chip 102 and the first chip 101, allowing only three leads of the leadframe to realize the external electrical connection of the two MOS transistors.

Referring to FIG. 4e, an upper encapsulant 112 is formed.

In this step, an upper encapsulant 112 is formed on the lower encapsulant 111 to encapsulate the second chip 102 and the wiring layer. For example, the upper encapsulant 112 is formed by injection molding of a plastic encapsulant, and the plastic encapsulant used in the present disclosure is an epoxy resin plastic encapsulant, which is low-cost and has good curing performance.

Referring to FIG. 4f, the substrate 105 is removed, forming the outer pads 151-153.

In this step, the substrate 105 at the bottom of the lower encapsulant 111 is removed by mechanical peeling. At this time, the heat sink island 124 and the bottom surfaces of the leads 121-123 of the leadframe are flush with the lower surface of the lower encapsulant 111 and are exposed. Then, the outer pads 151-153 are plated on the bottom surfaces of the exposed leads 121-123 by electroplating.

The complete structure of the stacked chip package structure 100 is formed using the above-described method. When the stacked chip package structure 100 is mounted on the printed circuit board, the outer pads 151-153 of the stacked chip package structure 100 are soldered to the printed circuit board. The outer pads 151-153 create a gap between the exposed surface of the heat sink island 124 and the surface of the printed circuit board, thereby improving the heat dissipation effect through airflow in the gap. The heat sink island 124 quickly transfers the working heat of the first chip 101 and the second chip 102 to the external environment of the stacked chip package structure 100, achieving effective heat dissipation and enhancing device reliability.

All steps in the present disclosure's electroplating process involve first forming electroplating protection on the surface through photolithography technology of exposure and development, and then forming a metal seed layer in the area to be electroplated by sputtering or copper sinking. The metal seed layer is made of copper and ensures the bonding force between the subsequent electroplated metal and the plastic encapsulant, while also providing a surface for electroplating to adhere conductive ions, ensuring effective electroplating.

All steps in the packaging process in the present disclosure utilize plastic sealing material injection molding to form a package. The plastic sealing material used in the present disclosure is an epoxy resin plastic sealing material, which is low-cost and has good curing performance.

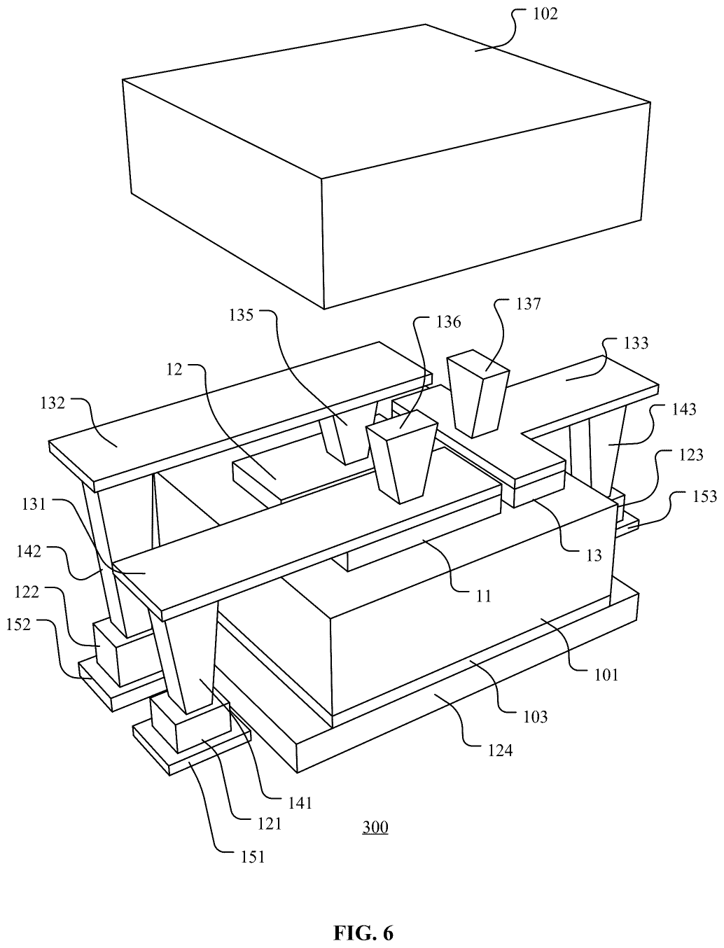

FIG. 5 is a perspective view of a stacked chip package structure according to a third embodiment of the present disclosure. For the sake of clarity, the lower encapsulant 111 for encapsulating the first chip 101 and the upper encapsulant 112 for encapsulating the second chip 102 are not shown in the figure.

The stacked chip package structure 200 comprises a lower encapsulant 111 and an upper encapsulant 112 (neither of which is shown in the figure), with a first chip 101 and a second chip 102 respectively enclosed inside the lower encapsulant 111 and the upper encapsulant 112. A plurality of wirings 131-133 are formed on the upper surface of the lower encapsulant 111, and a plurality of external pads 151-153 are formed on the lower surface of the lower encapsulant 111.

On the first surface of the first chip 101, internal pads 11-13 of the source, gate, and drain are formed. On the first surface of the second chip 102, internal pads 21-23 of the source, gate, and drain are formed. The plurality of wirings 131-133 of the wiring layer serve as internal electrical connection paths and external electrical connection paths between the second chip 102 and the first chip 101, allowing the MOS transistors in the first chip 101 and the second chip 102 to be coupled to the external pads 151-153.

In the stacked chip package structure 200 according to the third embodiment of the present disclosure, the plurality of wirings 131-133 of the wiring layer are formed with recesses 134, respectively. During the step of flipping the second chip 102, the internal pads 21-23 of the second chip 102 may be partially embedded in the recesses of the plurality of wirings 131-133 to achieve direct electrical contact between them, preventing insulating materials such as encapsulating resin from entering the recesses and causing poor contact. The recesses in the wiring layer also serve to hold the positions of the internal pads 21-23 of the second chip 102. In a preferred embodiment, the entire first surface of the second chip 102 is secured and secured to the upper surface of the lower encapsulant 111 using an insulating adhesive, ensuring that the internal pads 21-23 of the second chip 102 and the internal pads 11-13 of the first chip 101 maintain positional alignment during the injection molding of the plastic package, thereby improving the yield of the stacked chip package structure.

In the stacked chip package structure 200 according to the third embodiment of the present disclosure, there is direct electrical contact between the second chip 102 and the wiring layer. Since a conductive adhesive is not used, the internal electrical connection path and the external electrical connection path of the package structure can carry a large current, reducing line loss and improving the rated power of the device.

FIG. 6 is a perspective view of a stacked chip package structure according to a fourth embodiment of the present disclosure. For the sake of clarity, the lower encapsulant 111 for encapsulating the first chip 101 and the upper encapsulant 112 for encapsulating the second chip 102 are not shown in the figure.

The stacked chip package structure 300 comprises a lower encapsulant 111 and an upper encapsulant 112 (not shown in the figure), with a first chip 101 and a second chip 102 encapsulated inside the lower encapsulant 111 and the upper encapsulant 112, respectively. A plurality of wirings 131-133 are formed on the upper surface of the lower encapsulant 111, and a plurality of external pads 151-153 are formed on the lower surface of the lower encapsulant 111.

On the first surface of the first chip 101, internal pads 11-13 of the source, gate, and drain are formed. On the first surface of the second chip 102, internal pads 21-23 of the source, gate, and drain are formed. The plurality of wirings 131-133 of the wiring layer serve as internal electrical connection paths and external electrical connection paths between the second chip 102 and the first chip 101, allowing the MOS transistors in the first chip 101 and the second chip 102 to be coupled to the external pads 151-153.

In the stacked chip package structure 300 according to the fourth embodiment of the present disclosure, the plurality of wirings 131-133 of the wiring layer are located on different levels. For example, the source wiring 131 and the gate wiring 133 of the MOS transistor are located on the pad surface of the first chip 101, while the drain wiring 132 of the MOS transistor is located on the pad surface of the second chip 102. After performing the steps shown in FIGS. 4b and 4c, wirings 131 and 133 are formed on the upper surface of the lower encapsulant 111, penetrating the conductive vias 141 and 143 of the lower encapsulant 111. Then, an encapsulation layer is formed on the surface of the lower encapsulant 111 to cover the wirings 131 and 133. The steps shown in FIGS. 4b and 4c are then repeated, and the wiring 132 is formed on the upper surface of the encapsulation layer, penetrating the conductive vias 142 of the encapsulation layer and the lower encapsulant 111, as well as the conductive vias 135-137 of the encapsulation layer. In the step of flipping the second chip 102, the pads 22 of the second chip 102 are secured to the wiring layer 132 of the upper layer using a conductive adhesive, while the pads 21 and 23 of the second chip 102 are secured to the conductive vias 136 and 137, respectively. Therefore, the pad 22 of the second chip 102 is coupled to the pad 12 of the first chip 101 via the conductive adhesive, the wiring 132, and the conductive vias 135; the pad 21 of the second chip 102 is coupled to the pad 11 of the first chip 101 via the conductive adhesive, the conductive vias 136, and the wiring layer 131; and the pad 23 of the second chip 102 is coupled to the pad 13 of the first chip 101 via the conductive adhesive, the conductive vias 137, and the wiring layer 133, thereby realizing the internal electrical connection between the second chip 102 and the first chip 101.

In the stacked chip package structure according to the fourth embodiment of the present disclosure, the plurality of wirings 131-133 of the wiring layer are located on different levels. The wiring layer serves as both an internal electrical connection and an external electrical connection path between the first chip 101 and the second chip 102, allowing only the external pads 151-153 of a single chip to realize the external electrical connection of the two chips. Further, for MOS chips, designing the plurality of wirings 131-133 at different levels can effectively reduce electric-field coupling between the wirings and minimize the risk of breakdown due to insufficient insulation between the wirings, thereby significantly improving the withstand voltage characteristics and long-term reliability of the MOS chips.

It should be understood that the embodiments of the present disclosure have been described with reference to certain examples, and those skilled in the art will recognize that various modifications or equivalent substitutions can be made to these features and embodiments without departing from the spirit and scope of the present disclosure. Furthermore, based on the teachings of the present disclosure, these features and embodiments can be adapted to suit specific circumstances and materials, again without departing from the spirit and scope of the present disclosure. Therefore, the present disclosure is not limited to the specific embodiments described herein, and all embodiments falling within the scope of the claims are included in the protection afforded by the present disclosure.

What is claimed is:

1. A stacked chip package structure, comprising:
a lower encapsulant having a wiring layer on an upper surface of the lower encapsulant, a leadframe on a lower surface of the lower encapsulant, and a first chip encapsulated therein, the wiring layer comprising a plurality of wirings; and
an upper encapsulant above the lower encapsulant and encapsulating a second chip therein, wherein a plurality of internal pads of the first chip are disposed opposite to a plurality of internal pads of the second chip and are electrically coupled with each other via the plurality of wirings, thereby electrically coupling the first chip and the second chip within the stacked chip package structure, and
the plurality of wirings are coupled to a plurality of leads of the leadframe via a plurality of conductive vias within the lower encapsulant.

2. The stacked chip package structure according to claim 1, wherein the first chip and the second chip are a first MOS transistor and a second MOS transistor, respectively.

3. The stacked chip package structure according to claim 2, wherein a source, a gate, and a drain of the first MOS transistor are electrically coupled to a source, a gate, and a drain of the second MOS transistor, respectively, via the wiring layer.

4. The stacked chip package structure according to claim 2, wherein the leadframe comprises a heat sink island, a first surface of the first MOS transistor is formed with the plurality of internal pads, and a second surface of the first MOS transistor is opposite to the first surface and adhered to the heat sink island.

5. The stacked chip package structure according to claim 2, further comprising:
a plurality of external pads on the lower surface of the lower encapsulant and electrically coupled to the plurality of leads, respectively.

6. The stacked chip package structure according to claim 2, wherein the plurality of internal pads of the second chip are adhered to the wiring layer using a conductive adhesive to achieve electrical connection.

7. The stacked chip package structure according to claim 2, wherein each of the plurality of wirings has a recess;
and the plurality of internal pads of the second chip are positioned within the respective recesses to achieve electrical connection.

8. The stacked chip package structure according to claim 7, wherein the second chip is secured to the upper surface of the lower encapsulant using an insulating adhesive.

9. The stacked chip package structure according to claim 2, wherein the plurality of wirings are located in wiring layers of different levels, at least one internal pad of the first chip is coupled to a respective wiring via a conductive via, and at least one internal pad of the second chip is coupled to a respective wiring via a conductive via.

10. A method for forming a stacked chip package structure, comprising:
mounting a first chip upwards on a heat sink island of a leadframe;
forming a lower encapsulant encapsulating the first chip and the leadframe, with a plurality of internal pads of the first chip being exposed on an upper surface of the lower encapsulant, and with the heat sink island and a plurality of leads of the leadframe being exposed on a lower surface of the lower encapsulant;
forming an interconnect structure comprising a plurality of wirings on the upper surface of the lower encapsulant, and a plurality of conductive vias penetrating the lower encapsulant to the plurality of leads;
mounting a second chip downwards on the lower encapsulant such that a plurality of internal pads of the first chip and a plurality of internal pads of the second chip are disposed opposite to each other and are electrically coupled via the plurality of wirings; and
forming an upper encapsulant above the lower encapsulant and encapsulating the second chip,
wherein the wiring layer electrically couples the first chip and the second chip within the stacked chip package structure.

11. The method according to claim 10, wherein the first chip and the second chip are a first MOS transistor and a second MOS transistor, respectively.

12. The method according to claim 11, wherein a source, a gate, and a drain of the first MOS transistor are electrically coupled to a source, a gate, and a drain of the second MOS transistor, respectively, via the wiring layer.

13. The method according to claim 11, wherein mounting the second chip downwards on the lower encapsulant comprises:
adhering the plurality of internal pads of the second chip to the wiring layer using a conductive adhesive to achieve electrical connection.

14. The method according to claim 11, wherein mounting the second chip downwards on the lower encapsulant comprises:
forming recesses in the plurality of wirings, respectively;
and positioning the plurality of internal pads of the second chip within the respective recesses to achieve electrical connection.

15. The method according to claim 11, wherein mounting the second chip downwards on the lower encapsulant further comprises:
securing the second chip to the upper surface of the lower encapsulant using an insulating adhesive.

16. The method according to claim 11, wherein forming the interconnect structure comprises:
forming the plurality of wirings in wiring layers of different levels;
and at least one internal pad of the first chip is coupled to a corresponding wiring via a conductive via;
and at least one internal pad of the second chip is coupled to a corresponding wiring via a conductive via.
